(19) United States
(12) Patent Application Publication
(10) Pub. No.: US 2019/0229496 A1
(43) Pub. Date: Jul. 25, 2019

(54) NITRIDE SEMICONDUCTOR LASER AND ELECTRONIC APPARATUS

(71) Applicant: SONY CORPORATION, TOKYO (JP)

(72) Inventors: SHOICHIRO IZUMI, KANAGAWA (JP); TATSUSHI HAMAGUCHI, KANAGAWA (JP); SUSUMU SATO, KANAGAWA (JP); NORIYUKI FUTAGAWA, KANAGAWA (JP)

(21) Appl. No.: 16/316,450

(22) PCT Filed: May 19, 2017
(86) PCT No.: PCT/JP2017/018808

§ 371 Date: Jan. 9, 2019

(30) Foreign Application Priority Data
Jul. 27, 2016 (JP) 2016-146907

(51) Int. Cl. H01S 5/183; H01S 5/343; H01S 5/02; H01S 5/028

(52) U.S. Cl. CPC H01S 5/18361; H01S 5/18322; H01S 5/34333; H01S 5/0425; H01S 5/028; H01S 5/18369; H01S 5/0206

(57) ABSTRACT

A nitride semiconductor laser according to an embodiment of the disclosure includes a vertical resonator layer that includes an active layer, a current confining layer having an opening, and two DBR layers interposing the active layer and the opening therebetween. The nitride semiconductor laser further includes a resonance suppressing part disposed at a position that is outside the vertical resonator layer and that is opposed to at least the opening.

### TECHNICAL FIELD

The disclosure relates to a nitride semiconductor laser and an electronic apparatus including the same.

### BACKGROUND ART

The nitride semiconductor laser is capable of emitting laser light having a shorter wavelength than a semiconductor laser such as a silicon semiconductor laser and a gallium arsenide semiconductor laser. It is thus possible to fabricate a high-recording density optical disc and a high-definition laser printer by using the nitride semiconductor laser. Furthermore, it is also possible to easily fabricate a laser array by causing the nitride semiconductor laser to be of a surface light-emitting type. This enables parallel processing by many nitride semiconductor lasers; hence, it is expected to increase speed of the high-recording density optical disc and the high-definition laser printer. Such a nitride-based surface light-emitting laser is described in, for example, the following PTL 1.

### CITATION LIST

### Patent Literature

PTL 1: Japanese Unexamined Patent Application Publication No. 2015-35541

### SUMMARY OF THE INVENTION

Incidentally, a nitride-based surface light-emitting laser causes a noise which would not be observed with a surface light-emitting laser such as a silicon surface light-emitting laser and a gallium arsenide surface light-emitting laser. Accordingly, it is desirable to provide a nitride semiconductor laser that makes it possible to suppress occurrence of such a noise, and an electronic apparatus including the same.

A nitride semiconductor laser according to an embodiment of the disclosure includes a vertical resonator layer that includes an active layer, a current confining layer having an opening, and two DBR (distributed Bragg reflector) layers interposing the active layer and the opening therebetween. The nitride semiconductor laser further includes a resonance suppressing part disposed at a position that is outside the vertical resonator layer and that is opposed to at least the opening.

An electronic apparatus according to an embodiment of the disclosure includes the above-described nitride semiconductor laser as a light source.

In the nitride semiconductor laser and the electronic apparatus according to the respective embodiments of the disclosure, the resonance suppressing part is disposed at the position that is outside the vertical resonator layer and that is opposed to at least the opening of the current confining layer. This allows for suppressing resonance caused by light leaked from the vertical resonator layer being reflected by an interface outside the vertical resonator layer.

With the nitride semiconductor laser and the electronic apparatus according to the respective embodiments of the disclosure, the resonance is suppressed that is caused by the light leaked from the vertical resonator layer being reflected by the interface outside the vertical resonator layer. Hence, it is possible to suppress occurrence of a noise at the foot of an intensity spectrum of light generated by the vertical resonator layer, even in a case where the DBR layer does not have sufficient reflectance to the light from the active layer. It is to be noted that effects of the disclosure are not necessarily limited to those described here, and may include any of the effects described herein.

### BRIEF DESCRIPTION OF DRAWING

FIG. 1 is a diagram illustrating an example cross-sectional configuration of a surface light-emitting laser according to a first embodiment of the disclosure.

FIG. 2 is a diagram illustrating an example of an intensity spectrum of typical outgoing light.

FIG. 3 is a diagram illustrating an example of a manufacturing process of the surface light-emitting laser illustrated in FIG. 1.

FIG. 4 is a diagram illustrating an example of the manufacturing process following FIG. 3.

FIG. 5 is a diagram illustrating an example of the manufacturing process following FIG. 4.

FIG. 6 is a diagram illustrating an example cross-sectional configuration of a surface light-emitting laser according to a second embodiment of the disclosure.

FIG. 7 is a diagram illustrating an example cross-sectional configuration of a surface light-emitting laser according to a third embodiment of the disclosure.

FIG. 8 is a diagram illustrating an example cross-sectional configuration of a surface light-emitting laser according to a fourth embodiment of the disclosure.

FIG. 9 is a diagram illustrating an example cross-sectional configuration of a surface light-emitting laser according to a fifth embodiment of the disclosure.

FIG. 10 is a diagram illustrating an example cross-sectional configuration of a surface light-emitting laser according to a sixth embodiment of the disclosure.

FIG. 11 is a diagram illustrating an example cross-sectional configuration of an optical communication unit according to a seventh embodiment of the disclosure.

FIG. 12 is a diagram illustrating an example general configuration of a printer according to an eighth embodiment of the disclosure.

FIG. 13 is a diagram illustrating an example general configuration of an information reproducing/recording apparatus according to a ninth embodiment of the disclosure.

### MODES FOR CARRYING OUT THE INVENTION

In the following, embodiments of the disclosure are described in detail with reference to the drawings. The following description is merely a specific example of the disclosure and the disclosure should not be limited to the following embodiments. Moreover, the disclosure is not limited to arrangements, dimensions, dimensional ratio, and the like of the respective elements illustrated in the drawings. It is to be noted that description is made in the following order.

### 1. First Embodiment (Surface Light-Emitting Laser)

An example of a GaN substrate having an asperity surface on its back surface

### 2. Second Embodiment (Surface Light-Emitting Laser)

An example provided with a light absorbing layer in contact with the back surface of the GaN substrate

### 3. Third Embodiment (Surface Light-Emitting Laser)

An example provided with the light absorbing layer in contact with a top surface of the GaN substrate

### 4. Fourth Embodiment (Surface Light-Emitting Laser)

An example provided with an AR coating layer over a light emitting surface

### 5. Fifth Embodiment (Surface Light-Emitting Laser)

An example of a GaN substrate having an inclined surface on its back surface

### 6. Sixth Embodiment (Surface Light-Emitting Laser)

An example provided with an asperity layer in contact with the back surface of the GaN substrate

### 7. Seventh Embodiment (Optical Communication Unit)

An example using the surface light-emitting laser according to any of the above-described respective embodiments as a light source of an optical communication unit

### 8. Eighth Embodiment (Printer)

An example using the surface light-emitting laser according to any of the above-described respective embodiments as a light source of a printer

### 9. Ninth Embodiment (Information Reproducing/Recording Apparatus)

An example using the surface light-emitting laser according to any of the above-described respective embodiments as a light source of an information reproducing/recording apparatus

### 1. First Embodiment

### [Configuration]

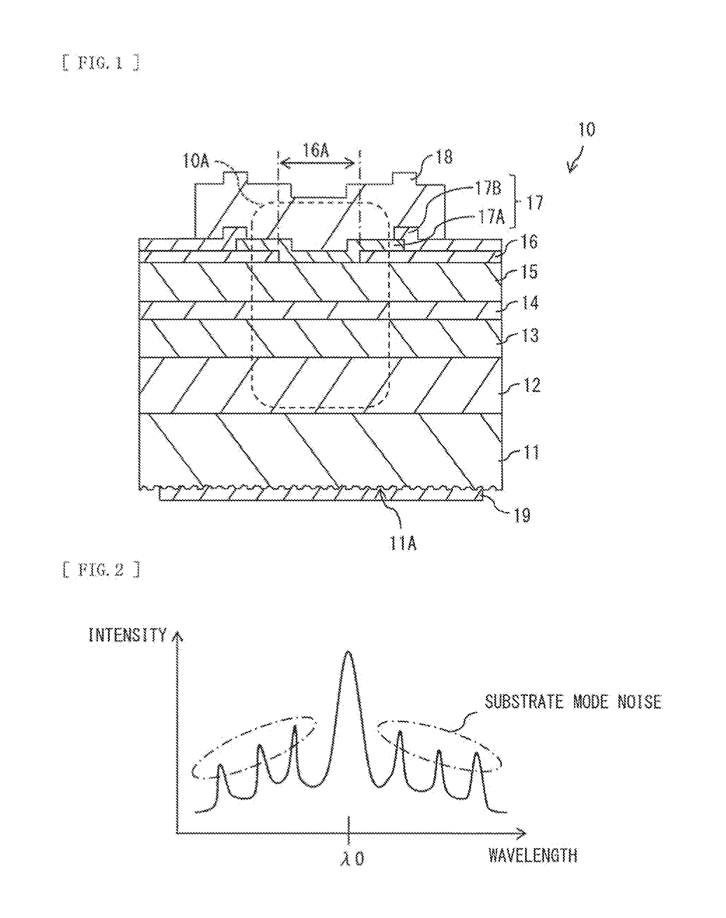

Described below is a configuration of a surface light-emitting laser 10 according to a first embodiment of the disclosure. FIG. 1 illustrates an example cross-sectional configuration of the surface light-emitting laser 1 according to the embodiment.

The surface light-emitting laser 10 is a top-surface emission type semiconductor laser preferably applicable as a light source for an optical disc, a laser printer, optical communication, or the like. The surface light-emitting laser 10 is a nitride semiconductor laser, and includes, for example, a vertical resonator layer 10A over a GaN substrate 11. The vertical resonator layer 10A is configured to be oscillated at a predetermined oscillation wavelength λ0 by two DBRs (distributed Bragg reflectors) opposed to each other in a normal direction to the GaN substrate 11. The vertical resonator layer 10A includes, for example, an active layer 14, a current confining layer 16 having an opening 16A, and two DBR layers (lower DBR layer 12 and upper DBR layer 18) that interpose the active layer 14 and the opening 16A therebetween. The GaN substrate 11 is a crystal growth substrate that has been used to epitaxially grow the DBR closer to the GaN substrate 11 of the two DBRs included in the vertical resonator layer 10A. That is, the GaN substrate 11 is a substrate disposed outside the vertical resonator layer 10A. Furthermore, the GaN substrate 11 is the substrate disposed on a side opposite to a light emission of the surface light-emitting laser 10 in terms of a positional relation to the vertical resonator layer 10A.

The surface light-emitting laser 10 includes a nitride semiconductor layer that includes, for example, the lower DBR layer 12, a lower spacer layer 13, the active layer 14, and an upper spacer layer 15 that are stacked over the GaN substrate 11 in this order. It is to be noted that the nitride semiconductor layer may include other layers than those described above. Furthermore, the lower spacer layer 13 and the upper spacer layer 15 may be excluded from the nitride semiconductor layer. The nitride semiconductor layer includes an AlGaInN-based compound semiconductor, such as GaN, AlGaN, AlInN, GaInN, and AlGaInN.

The lower DBR layer 12 includes, for example, a semiconductor multi-layer film. The semiconductor multi-layer film has a structure in which a low refractive index layer and a high refractive index layer are stacked alternately. A thickness of the low refractive index layer is preferably an odd multiple of λ0/4nᵢ (n₁ is a refractive index of the low refractive index layer). A thickness of the high refractive index layer is preferably an odd multiple of λ0/4n₂ (n₂ is a refractive index of the high refractive index layer). Example combinations of the low refractive index layer and the high refractive index layer in the semiconductor multi-layer film that configures the lower DBR layer 12 include GaN/AlGaN, GaN/AlInN, GaInN/GaN, and AlGaN/GaInN. The lower spacer layer 13 includes, for example, GaN. The GaN substrate 11, the lower DBR layer 12, and the lower spacer layer 13 include magnesium (Mg) or zinc (Zn), for example, as a p-type impurity. The upper spacer layer 15 includes, for example, GaN. The upper spacer layer 15 includes silicon (Si), for example, as an n-type impurity.

The active layer 14 has a quantum well structure, for example. The kind of the quantum well structure may be, for example, a single quantum well structure (QW structure) or a multiple quantum well structure (MQW structure). The quantum well structure has a structure in which a well layer and a barrier layer are stacked alternately. Example combinations of the well layer and the barrier layer include (In_{y}Ga_{(1-y)}N, GaN), (In_{y}Ga_{(1-y)}N, In_{z}Ga_{(1-z)}N) [where y>z], and (In_{y}Ga_{(1-y)}N, AlGaN).

The surface light-emitting laser 10 further includes, for example, the current confining layer 16, an upper electrode layer 17, and the upper DBR layer 18 that are provided over the upper spacer layer 15. The current confining layer 16 is a layer for confining a current to be injected to the active layer 14. The current confining layer 16 is configured by an insulating layer having an opening 16A. A portion of the upper spacer layer 15 is exposed on a bottom surface of the opening 16A. The insulating layer includes an insulating material such as SiO₂ and SiN. The insulating layer may be configured by a high resistance layer formed by ion implantation performed on a surface layer of the upper spacer layer 15, for example. A diameter of the opening 16A is, for example, 1 μm to 20 μm, and preferably about 10 μm.

The upper electrode layer 17 is configured by a transparent electrode layer 17A and a metal electrode layer 17B. The transparent electrode layer 17A includes an electrically-conductive material having transparency to light at the oscillation wavelength λ0 (e.g., equal to or less than absorptivity of 5%). Examples of the above-described electrically-conductive material include indium tin oxide (ITO: Indium Tin Oxide, including Sn doped In₂O₃, crystalline ITO, and amorphous ITO), indium zinc oxide (IZO: Iridium Zinc Oxide), IFO (F doped In₂O₃), tin oxide (SnO₂), ATO (Sb doped SnO₂), FTO (F doped SnO₂), zinc oxide (ZnO, including Al doped ZnO and B doped ZnO), InGaZnO-based material (such as InGaZnO₄, also referred to as “IGZO” hereinbelow), and ITiO (Ti doped ITO). The metal electrode layer 17B is configured by a single-layer film or a multilayer film containing at least one metal (including an alloy) selected from a group consisting of gold (Au), silver (Ag), palladium (Pd), platinum (Pt), nickel (Ni), Ti (Titanium), vanadium (V), tungsten (W), chromium (Cr), Al (aluminum), Cu (copper), Zn (zinc), tin (Sn), and indium (In), for example.

The upper DBR layer 18 is configured by, for example, a dielectric multilayer film. The dielectric multilayer film has a structure in which a low refractive index layer and a high refractive index layer having a thickness are stacked alternately. A thickness of the low refractive index layer is preferably an odd multiple of λ0/4n₃ (n₃ is a refractive index of the low refractive index layer). A thickness of the high refractive index layer is preferably an odd multiple of λ0/4n₄ (n₄ is a refractive index of the high refractive index layer). Example materials for the dielectric multilayer film that configures the upper DBR layer 18 include SiO₂, SiN, Al₂O₃, Nb₂O₅, Ta₂O₅, TiO₂, AlN, MgO, and ZrO₂. Example combinations of the low refractive index layer and the high refractive index layer in the dielectric multilayer film that configures the upper DBR layer 18 include SiO₂/SiN, SiO₂/Nb₂O₅, SiO₂/ZrO₂, and SiO₂/AlN. The dielectric multilayer film that configures the upper DBR layer 18 is formed by a film forming method such as sputtering, CVD, or vapor deposition.

The surface light-emitting laser 10 further includes a lower electrode layer 19 in contact with a back surface of the GaN substrate 11, for example. The lower electrode layer 19 has a structure in which, for example, titanium (Ti), platinum (Pt), and gold (Au) are stacked in this order from the GaN substrate 11 side (Ti/Pt/Au). The lower electrode layer 19 may have a structure in which, for example, vanadium (V), platinum (Pt), and gold (Au) are stacked in this order from the GaN substrate 11 side (V/Pt/Au). The lower electrode layer 19 may have a structure in which, for example, titanium (Ti), aluminum (Al), and gold (Au) are stacked in this order from the GaN substrate 11 side (Ti/Al/Au).

Incidentally, the surface light-emitting laser 10 includes a resonance suppressing part at a position that is outside the vertical resonator layer 10A and that is opposed to at least the opening 16A. The resonance suppressing part suppresses resonance caused by light leaked from the vertical resonator layer 10A being reflected by an interface outside the vertical resonator layer 10A. The resonance suppressing part suppresses occurrence of a noise (such as a substrate mode noise illustrated in FIG. 2) at the foot of an intensity spectrum of light (the light at the oscillation wavelength λ0) generated by the vertical resonator layer 10A.

In this embodiment, the resonance suppressing part is equivalent to the surface layer part of the GaN substrate 11. The GaN substrate 11 has, on the back surface of the GaN substrate, an asperity surface 11A rougher than a top surface of the GaN substrate. In the embodiment, the above-described resonance suppressing part is the asperity surface 11A. Surface roughness (root mean square roughness, RMS) of the asperity surface 11A is 1 nm or more. The surface roughness of the asperity surface 11A is derived from observation of the asperity surface 11A on the basis of a cross section measurement using TEM and SEM, for example. The surface roughness of the asperity surface 11A may be derived from observation of the asperity surface 11A on the basis of a plane measurement using AFM, for example.

### [Manufacturing Method]

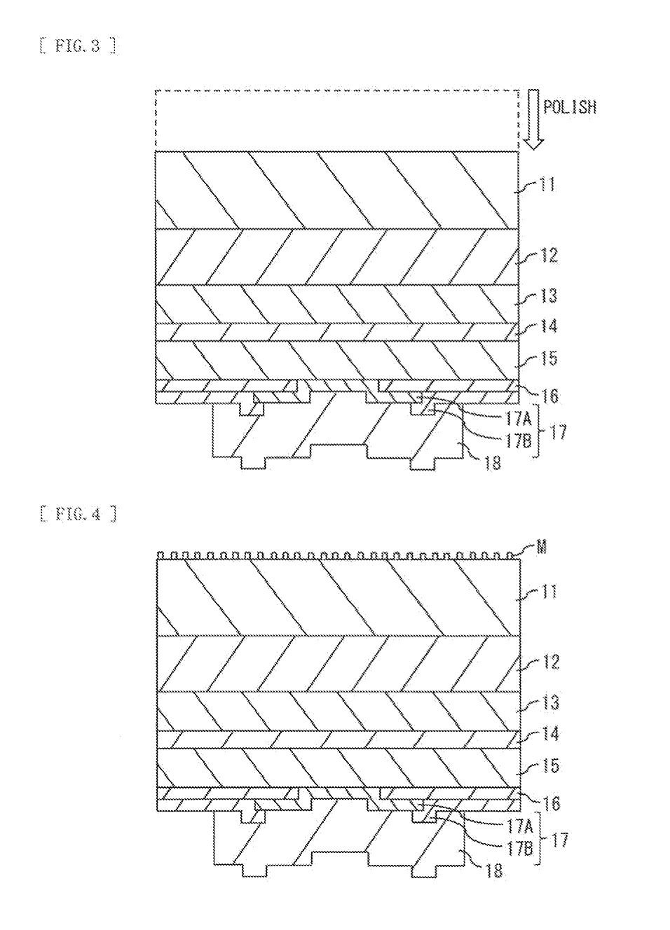

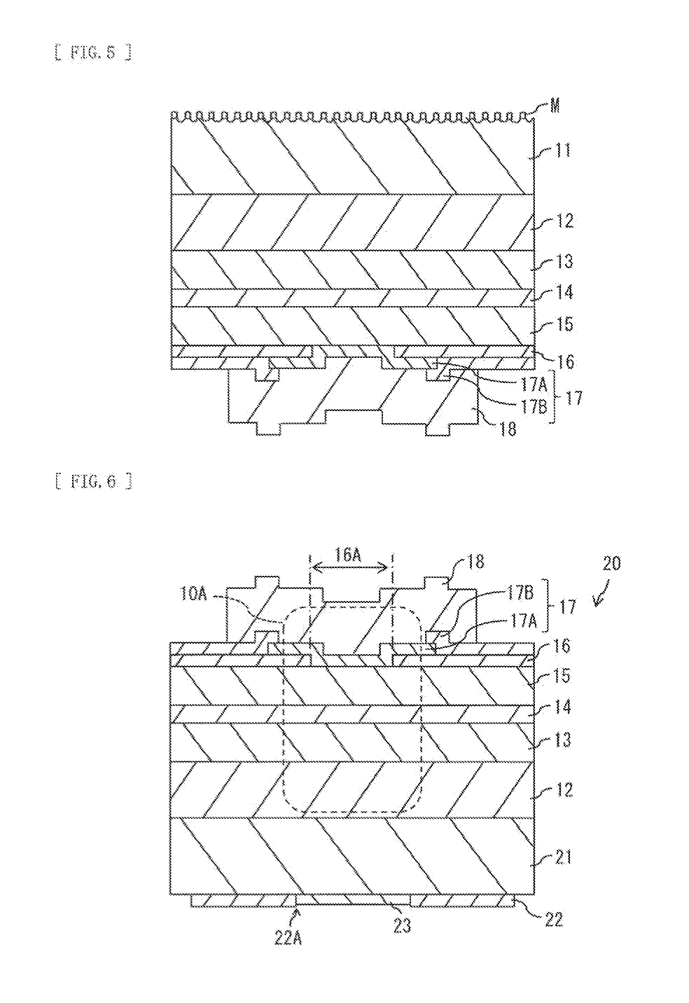

Next, a method of manufacturing the surface light-emitting laser 10 according to the embodiment is described. FIG. 3 illustrates an example of a manufacturing process of the surface light-emitting laser 10. FIG. 4 illustrates an example of the manufacturing process of the surface light-emitting laser 10 following FIG. 3. FIG. 5 illustrates an example of the manufacturing process of the surface light-emitting laser 10 following FIG. 4.

To manufacture the surface light-emitting laser 10, for example, a nitride semiconductor is formed collectively over the GaN substrate 11 by an epitaxial crystal growth method such as MOCVD (Metal Organic Chemical Vapor Deposition: metal organic chemical vapor deposition). In doing so, for a material of the compound semiconductor, trimethylgallium ((CH₃)₃Ga) is used as a source gas of Ga, trimethylaluminum ((CH₃)₃Al) is used as a source gas of Al, and trimethylindium ((CH₃)₃In) is used as a source gas of In, for example. Furthermore, ammonium (NH₃) is used as a source gas of N.

First, using the MOCVD method, for example, the lower DBR layer 12, the lower spacer layer 13, the active layer 14, and the upper spacer layer 15 are formed over the GaN substrate 11 in this order from the GaN substrate 11 side. Next, the current confining layer 16, the upper electrode layer 17, and the upper DBR layer 18 are formed over the upper spacer layer 15 in this order from the upper spacer layer 15 side using the film forming method such as sputtering, CVD, or vapor deposition, for example. Next, the GaN substrate 11 is reduced in thickness by polishing the back surface of the GaN substrate 11 (FIG. 4). As a polishing method in this process, for example, mechanical grinding, chemical mechanical polishing, or photoelectrochemical etching may be used.

Next, photoresist is applied to the back surface of the polished GaN substrate 11, and then a mask M having irregular openings is formed by exposure (FIG. 4). The back surface of the GaN substrate 11 is exposed in the openings of the mask M. Subsequently, the back surface of the GaN substrate 11 exposed in the openings of the mask M is taken off by dry etching or wet etching, for example (FIG. 5). Thereafter, the mask M is removed. This allows for formation of the asperity surface 11A on the back surface of the GaN substrate 11. The lower electrode layer 19 is then formed over the asperity surface 11A. In this manner, the surface light-emitting laser 10 according to the embodiment is manufactured.

### [Operation]

With the surface light-emitting laser 10 having such a configuration, when a predetermined voltage is applied between the upper electrode layer 17 and the lower electrode layer 19, the current is injected into the active layer 14 through the opening 16A, which causes light emission owing to recombination of electrons and holes. The light is reflected by a pair of lower DBR layer 12 and upper DBR layer 18, causing laser oscillation at the predetermined oscillation wavelength λ0. The laser light at the predetermined oscillation wavelength λ0 is then output from the top surface of the upper DBR layer 18 to the outside.

### [Effects]

Effects of the surface light-emitting laser 10 according to the embodiment are described next.

Compared to a surface light-emitting laser such as a silicon surface light-emitting laser and a gallium arsenide surface light-emitting laser, a nitride-based surface light-emitting laser tends to have a larger lattice mismatch which leads to cracking and difficulties in creating a difference in refractive index, due to its crystalline nature. This makes it difficult to provide the DBR for the nitride-based surface light-emitting laser. As a result, with the DBR, sufficient reflectance is often not available for the light from the active layer. When the reflectance of the DBR is insufficient, the light from the active layer is transmitted through the DBR. Hence, resonance occurs on the interface with the substrate or the like, causing a noise (the substrate mode noise) that would not be observed with a surface light-emitting laser such as the silicon surface light-emitting laser and the gallium arsenide surface light-emitting laser.

In contrast, according to the embodiment, the resonance suppressing part (asperity surface 11A) is disposed at the position that is outside the vertical resonator layer 10A and that is opposed to at least the opening 16A in the current confining layer 16. This allows for suppressing the resonance caused by light leaked from the vertical resonator layer 10A being reflected by the interface outside the vertical resonator layer 10A. As a result, even in a case where the lower DBR layer 12 does not have sufficient reflectance to the light from the active layer 14, it is possible to suppress occurrence of a noise at the foot of the intensity spectrum of the light generated by the vertical resonator layer 10A.

### 2. Second Embodiment

### [Configuration]

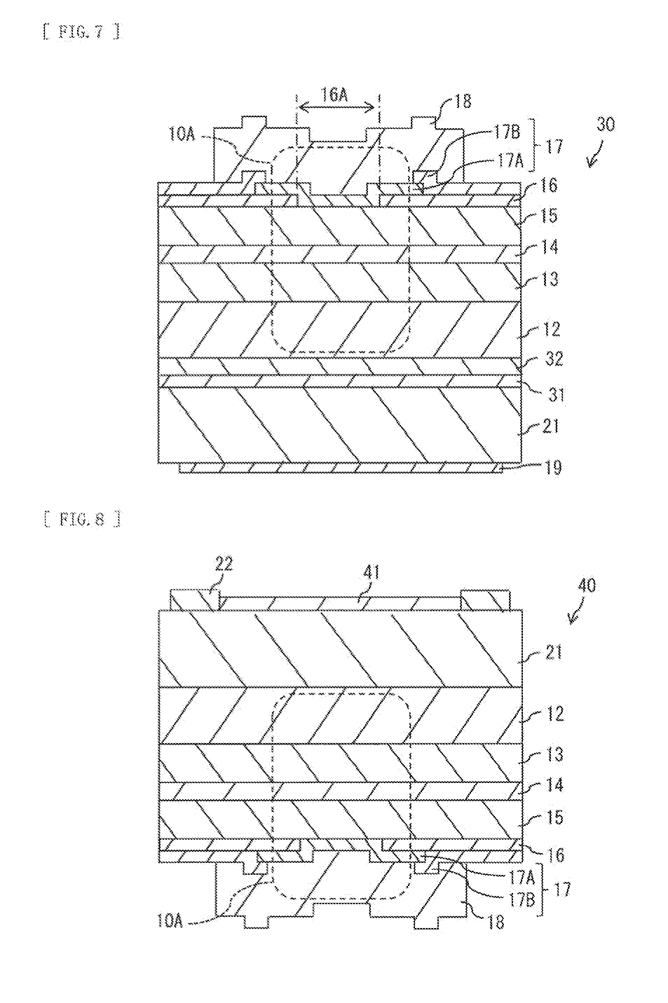

A surface light-emitting laser 20 according to a second embodiment of the disclosure is described next. FIG. 6 illustrates an example cross-sectional configuration of the surface light-emitting laser 20 according to the embodiment. The surface light-emitting laser 20 includes a GaN substrate 21 instead of the GaN substrate 11, and further includes a lower electrode layer 22 and a light absorbing layer 23 at the position of the lower electrode layer 19, in the surface light-emitting laser 10 according to the above-described embodiment.

That is, as with the GaN substrate 11, the GaN substrate 21 is a substrate disposed on a side opposite to a light emission of the surface light-emitting laser 20 in terms of a positional relation to the vertical resonator layer 10A. The back surface of the GaN substrate 21 is a flat surface, for example. It is to be noted that the back surface of the GaN substrate 21 may be the asperity surface 11A, for example.

The lower electrode layer 22 is a layer in contact with the back surface of the GaN substrate 21. The GaN substrate 21 has an opening 22A at a position opposing at least the opening 16A. The lower electrode layer 22 includes a material that is in common with the lower electrode layer 19, for example. The light absorbing layer 23 is a layer in contact with the back surface of the GaN substrate 21. The light absorbing layer 23 is disposed in the opening 22A. The light absorbing layer 23 is disposed at a position that is outside the vertical resonator layer 10A and that is opposed to at least the opening 16A. The light absorbing layer 23 is a layer having higher light absorptivity at the oscillation wavelength λ0 than the GaN substrate 21. The light absorbing layer 23 includes, for example, a dielectric material (such as SiN, SiO and TaO).

Incidentally, the surface light-emitting laser 20 includes the resonance suppressing part at the position that is outside the vertical resonator layer 10A and that is opposed to at least the opening 16A. The resonance suppressing part suppresses the resonance caused by light leaked from the vertical resonator layer 10A being reflected by the interface outside the vertical resonator layer 10A. The resonance suppressing part suppresses occurrence of a noise (such as the substrate mode noise illustrated in FIG. 2) at the foot of the intensity spectrum of light (the light at the oscillation wavelength λ0) generated by the vertical resonator layer 10A. In this embodiment, the resonance suppressing part is equivalent to the light absorbing layer 23.

### [Effects]

Effects of the surface light-emitting laser 20 according to the embodiment are described next. In this embodiment, the resonance suppressing part (light absorbing layer 23) is disposed at the position that is outside the vertical resonator layer 10A and that is opposed to at least the opening 16A of the current confining layer 16. This allows for suppressing the resonance caused by light leaked from the vertical resonator layer 10A being reflected by the interface outside the vertical resonator layer 10A. As a result, even in a case where the lower DBR layer 12 does not have sufficient reflectance to the light from the active layer 14, it is possible to suppress occurrence of a noise at the foot of the intensity spectrum of the light generated by the vertical resonator layer 10A.

### 3. Third Embodiment

### [Configuration]

A surface light-emitting laser 30 according to a third embodiment of the disclosure is described next. FIG. 7 illustrates an example cross-sectional configuration of the surface light-emitting laser 30 according to the embodiment. The surface light-emitting laser 30 includes the lower electrode layer 19 instead of the lower electrode layer 22 and the light absorbing layer 23, and further includes a light absorbing layer 31 and an underlayer 32 between the top surface of the GaN substrate 21 and the lower DBR layer 12, in the surface light-emitting laser 20 according to the above-described second embodiment.

That is, the lower electrode layer 19 is a layer in contact with the back surface of the GaN substrate 21. The light absorbing layer 31 is a layer in contact with the top surface of the GaN substrate 21. The light absorbing layer 31 is disposed at the position that is outside the vertical resonator layer 10A and that is opposed to at least the opening 16A. The light absorbing layer 31 is a layer having higher light absorptivity at the oscillation wavelength λ0 than the GaN substrate 21. The light absorbing layer 31 includes, for example, a material having a bandgap wider than the bandgap of the active layer 14, for example (such as GaInN). The underlayer 32 is a layer that has been used to epitaxially grow the DBR closer to the GaN substrate 11 of the two DBRs included in the vertical resonator layer 10A, and includes GaN, for example.

Incidentally, the surface light-emitting laser 30 includes the resonance suppressing part at the position that is outside the vertical resonator layer 10A and that is opposed to at least the opening 16A. The resonance suppressing part suppresses the resonance caused by light leaked from the vertical resonator layer 10A being reflected by the interface outside the vertical resonator layer 10A. The resonance suppressing part suppresses occurrence of a noise (such as the substrate mode noise illustrated in FIG. 2) at the foot of the intensity spectrum of light (the light at the oscillation wavelength λ0) generated by the vertical resonator layer 10A. In this embodiment, the resonance suppressing part is equivalent to the light absorbing layer 31.

### [Effects]

Effects of the surface light-emitting laser 30 according to the embodiment are described next. In this embodiment, the resonance suppressing part (light absorbing layer 31) is disposed at the position that is outside the vertical resonator layer 10A and that is opposed to at least the opening 16A of the current confining layer 16. This allows for suppressing the resonance caused by light leaked from the vertical resonator layer 10A being reflected by the interface outside the vertical resonator layer 10A. As a result, even in a case where the lower DBR layer 12 does not have sufficient reflectance to the light from the active layer 14, it is possible to suppress occurrence of a noise at the foot of the intensity spectrum of the light generated by the vertical resonator layer 10A

### Fourth Embodiment

### [Configuration]

A surface light-emitting laser 40 according to a fourth embodiment of the disclosure is described next. FIG. 8 illustrates an example cross-sectional configuration of the surface light-emitting laser 40 according to the embodiment. The surface light-emitting laser 40 has a configuration in which reflectance of the upper DBR layer 18 is made higher and in which a leakage of light from the upper DBR layer 18 side is made difficult, in the surface light-emitting laser 20 according to the above-described second embodiment. The surface light-emitting laser 40 further includes an AR (Anti-Reflection) coating layer 41 instead of the light absorbing layer 23, in the surface light-emitting laser 20 according to the above-described second embodiment.

That is, in the surface light-emitting laser 40, the GaN substrate 21 is disposed on the light emission side of the surface light-emitting laser 40 in terms of a positional relation to the vertical resonator layer 10A, and the back surface of the GaN substrate 21 serves as the light emitting surface. Furthermore, the AR coating layer 41 serves as a layer in contact with the back surface (light emitting surface) of the GaN substrate 21. The AR coating layer 41 is a thin coating that suppresses reflection at a surface of the GaN substrate 21 using interference of light.

Incidentally, the surface light-emitting laser 40 includes the resonance suppressing part at the position that is outside the vertical resonator layer 10A and that is opposed to at least the opening 16A. The resonance suppressing part suppresses the resonance caused by light leaked from the vertical resonator layer 10A being reflected by the interface outside the vertical resonator layer 10A. The resonance suppressing part suppresses occurrence of a noise (such as the substrate mode noise illustrated in FIG. 2) at the foot of the intensity spectrum of light (the light at the oscillation wavelength λ0) generated by the vertical resonator layer 10A. In this embodiment, the resonance suppressing part is equivalent to the AR coating layer 41.

### [Effects]

Effects of the surface light-emitting laser 40 according to the embodiment are described next. In this embodiment, the resonance suppressing part (AR coating layer 41) is disposed at the position that is outside the vertical resonator layer 10A and that is opposed to at least the opening 16A of the current confining layer 16. This allows for suppressing the resonance caused by light leaked from the vertical resonator layer 10A being reflected by the interface outside the vertical resonator layer 10A. As a result, even in a case where the lower DBR layer 12 is disposed closer to the light emitting surface, it is possible to suppress occurrence of a noise at the foot of the intensity spectrum of the light generated by the vertical resonator layer 10A.

### 5. Fifth Embodiment

### [Configuration]

A surface light-emitting laser 50 according to a fifth embodiment of the disclosure is described next. FIG. 9 illustrates an example cross-sectional configuration of the surface light-emitting laser 50 according to the embodiment. The surface light-emitting laser 50 includes a GaN substrate 51 instead of the GaN substrate 11, in the surface light-emitting laser 10 according to the above-described first embodiment.

That is, as with the GaN substrate 11, the GaN substrate 51 is a layer disposed on a side opposite to a light emission of a surface light-emitting laser 25, in terms of a positional relation to the vertical resonator layer 10A. The back surface of the GaN substrate 51 is an inclined surface 51A having a normal that intersects a normal of a top surface of the GaN substrate 51. The GaN substrate 51 has the inclined surface 51A on the back surface thereof. An angle formed by the normal of the inclined surface 51A and the normal of the top surface of the GaN substrate 51 is 0.05 degrees or more, and preferably 0.5 degrees or more. The inclined surface 51A is formed by, for example, polishing the back surface of the GaN substrate 51. The lower electrode layer 19 is a layer in contact with the back surface (inclined surface 51A) of the GaN substrate 51.

Incidentally, the surface light-emitting laser 50 includes the resonance suppressing part at the position that is outside the vertical resonator layer 10A and that is opposed to at least the opening 16A. The resonance suppressing part suppresses the resonance caused by light leaked from the vertical resonator layer 10A being reflected by the interface outside the vertical resonator layer 10A. The resonance suppressing part suppresses occurrence of a noise (such as the substrate mode noise illustrated in FIG. 2) at the foot of the intensity spectrum of light (the light at the oscillation wavelength λ0) generated by the vertical resonator layer 10A. In this embodiment, the resonance suppressing part is equivalent to the inclined surface 51A.

### [Effects]

Effects of the surface light-emitting laser 50 according to the embodiment are described next. In this embodiment, the resonance suppressing part (inclined surface 51A) is disposed at the position that is outside the vertical resonator layer 10A and that is opposed to at least the opening 16A of the current confining layer 16. This allow for suppressing the resonance caused by light leaked from the vertical resonator layer 10A being reflected by the interface outside the vertical resonator layer 10A. As a result, even in a case where the lower DBR layer 12 does not have sufficient reflectance to the light from the active layer 14, it is possible to suppress occurrence of a noise at the foot of the intensity spectrum of the light generated by the vertical resonator layer 10A.

### 6. Sixth Embodiment

### [Configuration]

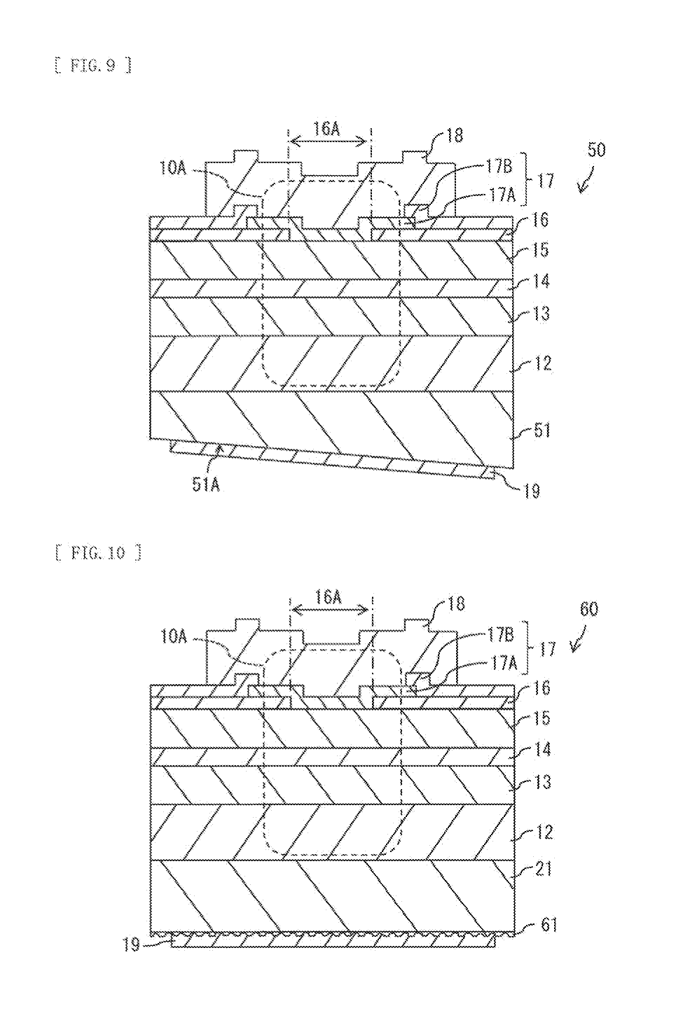

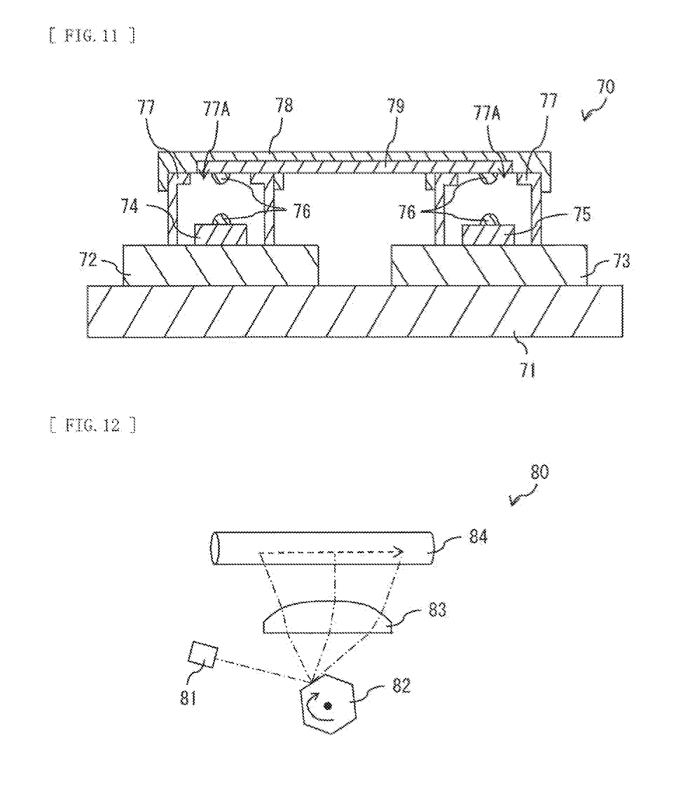

A surface light-emitting laser 60 according to a sixth embodiment of the disclosure is described next. FIG. 10 illustrates an example cross-sectional configuration of the surface light-emitting laser 60 according to the embodiment. The surface light-emitting laser 60 excludes the light absorbing layer 31 and the underlayer 32, and further includes an asperity layer 61 between the back surface of the GaN substrate 21 and the lower electrode layer 19, in the surface light-emitting laser 30 according to the above-described third embodiment. The asperity layer 61 is a layer having a non-uniform density in a plane. The asperity layer 61 is a layer formed through dispersion of fine particles on the back surface of the GaN substrate 21, for example, and has openings throughout the asperity layer 61. Thus, the lower electrode layer 19 is in contact with the back surface of the GaN substrate 21 through the openings of the asperity layer 61. In a case where the asperity layer 61 is the layer formed through the dispersion of the fine particles on the back surface of the GaN substrate 21, the fine particles configuring the asperity layer 61 may have electrical conductivity or electrical insulation.

Incidentally, the surface light-emitting laser 60 includes the resonance suppressing part at the position that is outside the vertical resonator layer 10A and that is opposed to at least the opening 16A. The resonance suppressing part suppresses the resonance caused by light leaked from the vertical resonator layer 10A being reflected by the interface outside the vertical resonator layer 10A. The resonance suppressing part suppresses occurrence of a noise (such as the substrate mode noise illustrated in FIG. 2) at the foot of the intensity spectrum of light (the light at the oscillation wavelength λ0) generated by the vertical resonator layer 10A. In this embodiment, the resonance suppressing part is equivalent to the asperity layer 61.

### [Effects]

Effects of the surface light-emitting laser 60 according to the embodiment are described next. In this embodiment, the resonance suppressing part (asperity layer 61) is disposed at the position that is outside the vertical resonator layer 10A and that is opposed to at least the opening 16A of the current confining layer 16. This allows for suppressing the resonance caused by light leaked from the vertical resonator layer 10A being reflected by the interface outside the vertical resonator layer 10A. As a result, even in a case where the lower DBR layer 12 does not have sufficient reflectance to the light from the active layer 14, it is possible to suppress occurrence of a noise at the foot of the intensity spectrum of the light generated by the vertical resonator layer 10A.

### 7. Seventh Embodiment

### [Configuration]

An optical communication unit 70 according to a seventh embodiment of the disclosure is described next. FIG. 11 illustrates an example cross-sectional configuration of the optical communication unit 70 according to the embodiment. The optical communication unit 70 includes two LSI chips 72 and 73 mounted over a printed wiring board 71. A light emitting device 74 is disposed over a surface of one LSI chip 71. The light emitting device 74 is any one of the surface light-emitting lasers 10 to 60 according to the above-described respective embodiments. An electrical signal from the LSI chip 72 is converted into an optical signal by the light emitting device 74, and the optical signal is output from the light emitting device 74. A light-receiving device 75 such as a photodiode is disposed on the surface of the other LSI chip 73. An optical signal input to the light-receiving device 75 is converted into an electrical signal by the light-receiving device 75, and the electrical signal is input to the LSI chip 73.

Lenses 76 are disposed over the light emitting surface of the light emitting device 74, the light emitting surface of the light-receiving device 75, and at both ends of an optical waveguide 79. The lenses 76 are each a collimating lens that collimates divergent light and collects collimated light, for example. Moreover, a cylindrical male connector 77 that covers the light emitting device 74 and the light-receiving device 75 is disposed on top surfaces of the LSI chips 72 and 73. A top surface of the male connector 77 is provided with an opening 77A and a female connector 78 that occludes the opening 77A and fits to the male connector 77. The female connector 78 is disposed along the optical waveguide 79, and also has a function of supporting the optical waveguide 79.

In this embodiment, when the light emitting device 74 is driven after the male connector 77 and the female connector 78 are coupled to each other, the light emitting device 74 emits light and the light enters one end of the optical waveguide 79 via the lens 76. The light that has entered the optical waveguide 79 is output from the other end of the optical waveguide 79 after being guided through the optical waveguide 79, and then enters the light-receiving device 75 via the lens 76. The light that has entered the light-receiving device 75 is converted into an electrical signal (photocurrent) corresponding to an output level of the incident light, and then the electrical signal is output to the LSI chip 73.

Incidentally, in this embodiment, any one of the surface light-emitting lasers 10 to 60 according to the above-described respective embodiments is used in the optical communication unit 70. Hence, it is possible to allow the light emitting device 74 to operate at high speed.

In the above-described seventh embodiment, the optical communication unit 70 may include a plurality of light emitting devices 74; moreover, in the above-described seventh embodiment, the optical communication unit 70 may include a plurality of light-receiving devices 75.

### 8. Eighth Embodiment

### [Configuration]

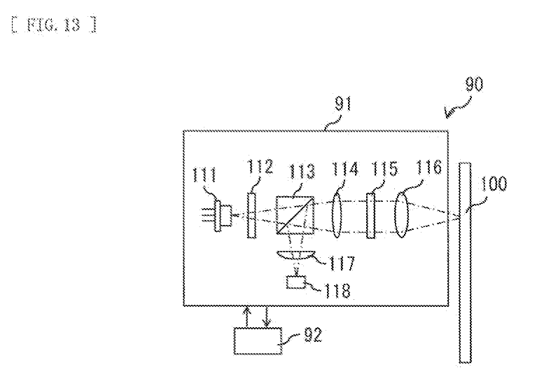

A printer 80 according to an eighth embodiment of the disclosure is described next. FIG. 12 illustrates an example general configuration of the printer 80 according to the embodiment. The printer 80 includes, for example, a light source 81, a polygon mirror 82 that reflects light from the light source 81 and performs scanning of the reflected light, an fθ lens 83 that guides the light from the polygon mirror 82 to a photosensitive drum 84, the photosensitive drum 84 that forms an electrostatic latent image by receiving the light from the fθ lens 83, and a toner feeder (not illustrated) that attaches a toner corresponding to the electrostatic latent image onto the photosensitive drum 84.

Any one of the surface light-emitting lasers 10 to 60 according to the above-described respective embodiments is used as the light source 81 in the printer 80. Hence, it is possible to allow the light source 81 to operate at high speed.

### 9. Ninth Embodiment

### [Configuration]

An information reproducing/recording apparatus 90 according to a ninth embodiment of the disclosure is described next. FIG. 13 illustrates an example general configuration of the information reproducing/recording apparatus 90 according to the embodiment. The information reproducing/recording apparatus 90 includes, for example, an optical unit 91 and an information processing part 82.

The information processing part 82 obtains information recorded on a recording medium 100 from the optical unit 91 and/or transmits recorded information to the optical unit 91. On the other hand, the optical unit 91 is used as an optical pickup unit for high-recording density recording and reproduction for a DVD or the like, and includes a semiconductor laser LD as a light source and an optical system disposed between the semiconductor laser LD and a region where the recording medium 100 such as the DVD is placed. The semiconductor laser LD is configured by any one of the surface light-emitting lasers 10 to 60 according to the above-described respective embodiments. A large number of pits (protrusions) having a size of several μm, for example, are formed on the surface of the recording medium 100. The optical system is disposed in an optical path from the semiconductor laser LD to the recording medium 100, and includes, for example, a grating (GRT) 112, a polarizing beam splitter (PBS) 113, a collimating lens (CL) 114, a quarter wavelength plate (λ/4 plate) 115, and an objective lens (OL) 116. Moreover, the optical system includes a cylindrical lens (CyL) 117 and a light-receiving device (PD) 118 such as a photodiode on the optical path split by the polarizing beam splitter (PBS) 113.

In the optical unit 91, light from the light source (semiconductor laser LD) passes through the GRT 112, the PBS 113, the CL 114, the λ/4 plate 115, and the OL 116 to be focused on the recording medium 100 and then reflected by the pits on the surface of the recording medium 100. The reflected light passes through the OL 116, the λ/4 plate 115, the CL 114, the PBS 113, and the CyL 117 to enter the PD 118 to be subjected to reading of a pit signal, a tracking signal, and a focus signal.

The optical unit 91 according to the embodiment uses any one of the surface light-emitting lasers 10 to 60 according to the above-described respective embodiments as the semiconductor laser LD as described above. Hence, it is possible to allow the semiconductor laser LD to operate at high speed.

Although the disclosure has been described with reference to a plurality of embodiments above, the disclosure is not limited to the above-described respective embodiments but various modifications are possible. It is to be noted that the effects described herein are merely examples. The effects of the disclosure are not limited to those described herein. The disclosure may have effects other than those described herein.

Moreover, the disclosure may have the following configurations.

(1)

A nitride semiconductor laser including:

a vertical resonator layer that includes an active layer, a current confining layer having an opening, and two DBR (distributed Bragg reflector) layers interposing the active layer and the opening therebetween; and

a resonance suppressing part disposed at a position that is outside the vertical resonator layer and that is opposed to at least the opening.

(2)

The nitride semiconductor laser according to (1), further including a GaN substrate disposed outside the vertical resonator layer, in which

the resonance suppressing part is either a surface layer part of the GaN substrate or a layer in contact with a surface of the GaN substrate.

(3)

The nitride semiconductor laser according to (2), in which

the GaN substrate is a substrate disposed on a side opposite to a light emission of the nitride semiconductor laser in terms of a positional relation to the vertical resonator layer, and has, on a back surface of the GaN substrate, an asperity surface that is rougher than a top surface of the GaN substrate, and

the resonance suppressing part is the asperity surface.

(4)

The nitride semiconductor laser according to (2), in which

the GaN substrate is a substrate disposed on a side opposite to a light emission of the nitride semiconductor laser in terms of a positional relation to the vertical resonator layer, and

the resonance suppressing part is the layer in contact with the surface of the GaN substrate, and is a light absorbing layer having higher light absorptivity at an oscillation wavelength than the GaN substrate.

(5)

The nitride semiconductor laser according to (2), in which

the GaN substrate is disposed on a light emission side of the nitride semiconductor laser in terms of a positional relation to the vertical resonator layer, and

the resonance suppressing part is the layer in contact with the surface of the GaN substrate, and is an AR (Anti-Reflection) coating layer that suppresses reflection at the surface of the GaN substrate.

(6)

The nitride semiconductor laser according to (2), in which

the GaN substrate is a substrate disposed on a side opposite to a light emission of the nitride semiconductor laser in terms of a positional relation to the vertical resonator layer, and has an inclined surface on a back surface of the GaN substrate, and

the resonance suppressing part is the inclined surface.

(7)

The nitride semiconductor laser according to (2), in which

the GaN substrate is a substrate disposed on a side opposite to a light emission of the nitride semiconductor laser in terms of a positional relation to the vertical resonator layer, and

the resonance suppressing part is an asperity layer having a non-uniform density in a plane.

(8)

An electronic apparatus that includes a nitride semiconductor laser as a light source, the nitride semiconductor laser including:

a vertical resonator layer that includes an active layer, a current confining layer having an opening, and two DBR (distributed Bragg reflector) layers interposing the active layer and the opening therebetween; and

a resonance suppressing part disposed at a position that is outside the vertical resonator layer and that is opposed to at least the opening.

This application claims the priority of Japanese Priority Patent Application JP2016-146907 filed with the Japanese Patent Office on Jul. 27, 2016, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A nitride semiconductor laser comprising:
a vertical resonator layer that includes an active layer, a current confining layer having an opening, and two DBR (distributed Bragg reflector) layers interposing the active layer and the opening therebetween; and
a resonance suppressing part disposed at a position that is outside the vertical resonator layer and that is opposed to at least the opening.

2. The nitride semiconductor laser according to claim 1, further comprising a GaN substrate disposed outside the vertical resonator layer, wherein
the resonance suppressing part is either a surface layer part of the GaN substrate or a layer in contact with a surface of the GaN substrate.

3. The nitride semiconductor laser according to claim 2, wherein
the GaN substrate is a substrate disposed on a side opposite to a light emission of the nitride semiconductor laser in terms of a positional relation to the vertical resonator layer, and has, on a back surface of the GaN substrate, an asperity surface that is rougher than a top surface of the GaN substrate, and
the resonance suppressing part is the asperity surface.

4. The nitride semiconductor laser according to claim 2, wherein
the GaN substrate is a substrate disposed on a side opposite to a light emission of the nitride semiconductor laser in terms of a positional relation to the vertical resonator layer, and
the resonance suppressing part is the layer in contact with the surface of the GaN substrate, and is a light absorbing layer having higher light absorptivity at an oscillation wavelength than the GaN substrate.

5. The nitride semiconductor laser according to claim 2, wherein
the GaN substrate is disposed on a light emission side of the nitride semiconductor laser in terms of a positional relation to the vertical resonator layer, and
the resonance suppressing part is the layer in contact with the surface of the GaN substrate, and is an AR (Anti-Reflection) coating layer that suppresses reflection at the surface of the GaN substrate.

6. The nitride semiconductor laser according to claim 2, wherein
the GaN substrate is a substrate disposed on a side opposite to a light emission of the nitride semiconductor laser in terms of a positional relation to the vertical resonator layer, and has an inclined surface on a back surface of the GaN substrate, and
the resonance suppressing part is the inclined surface.

7. The nitride semiconductor laser according to claim 2, wherein
the GaN substrate is a substrate disposed on a side opposite to a light emission of the nitride semiconductor laser in terms of a positional relation to the vertical resonator layer, and
the resonance suppressing part is an asperity layer having a non-uniform density in a plane.

8. An electronic apparatus that includes a nitride semiconductor laser as a light source, the nitride semiconductor laser comprising:
a vertical resonator layer that includes an active layer, a current confining layer having an opening, and two DBR (distributed Bragg reflector) layers interposing the active layer and the opening therebetween; and
a resonance suppressing part disposed at a position that is outside the vertical resonator layer and that is opposed to at least the opening.
